(19) United States
(12) Patent Application Publication
(10) Pub. No.: US 2026/0149932 A1
(43) Pub. Date: May 28, 2026

(54) HEAT DISSIPATION MODULE

(71) Applicant: AAC Microtech (Changzhou) Co., Ltd., Changzhou City (CN)

(72) Inventors: Zhang Ren, Changzhou (CN); Ronglin Linghu, Changzhou (CN); Yun Tang, Changzhou (CN)

(21) Appl. No.: 19/237,039

(22) Filed: Jun. 13, 2025

Related U.S. Application Data
(63) Continuation of application No. PCT/CN2024/134307, filed on Nov. 25, 2024.

(51) Int. Cl. H04R 9/02; H04R 7/12; H04R 7/18; H04R 9/04; H04R 9/06; H05K 7/20

(52) U.S. Cl. CPC H04R 9/022; H04R 7/127; H04R 7/18; H04R 9/025; H04R 9/045; H04R 9/063; H05K 7/20336; H04R 2400/11

(57) ABSTRACT

A heat dissipation module, including vapor chamber and sound-producing device attached and fixed to vapor chamber; vapor chamber includes vapor chamber body having receiving cavity, capillary wick in receiving cavity, and opening on side of vapor chamber body close to sound-producing device; opening connects receiving cavity with outside, sound-producing device is supported by vapor chamber body and fixed to opening to seal opening, and receiving cavity is filled with heat dissipation liquid; sound-producing device includes magnetic circuit unit spaced apart from vapor chamber, and first vibration unit and second vibration unit on opposite sides of magnetic circuit unit. Magnetic circuit unit drives first vibration unit and second vibration unit to vibrate; sound-producing device includes first frame, one end of first frame is fixed to side of magnetic circuit unit close to vapor chamber, and another end of first frame is supported by vapor chamber and arranged around opening.

### TECHNICAL FIELD

The present disclosure relates to the technical field of electronic device and, in particular, to a head dissipation module.

### BACKGROUND

With the continuous development of society, the communication industry has always paid great attention to the heat dissipation of electronic devices such as mobile phones and tablets. With the advent of the 5G era, the power of heating elements and speakers has become larger and the temperature has become higher, resulting in poor thermal reliability of heating elements and speakers. As a heat dissipation element, the heat dissipation module is thin and lightweight, and because it has a divergent steam path and good 2D surface thermal conductivity, its heat dissipation effect is better than that of the finned radiator. Applying the heat dissipation module to electronic devices can avoid performance loss caused by poor heat dissipation of the product.

In the related art, the heat dissipation module generally includes a sound-producing device and a vapor chamber installed on the sound-producing device, and the heat generated during the operation of the sound-producing device is dissipated through the vapor chamber. The commonly used vapor chamber includes a housing, a capillary wick formed in the housing, a plurality of support columns arranged in the housing, and a liquid working substance arranged in the capillary wick. The sound-producing device is attached and installed on the heat source surface of the housing, and the head is carried to the head dissipation surface of the housing through the circulation of the liquid working substance with the capillary wick for heat dissipation. However, since the sound-producing device is installed on the housing, the overall installation space is increased. Meanwhile, after the water vapor condenses, the VC vapor chamber used inside the mobile phone relies on gravity and capillary action to passively reflux, which can easily lead to delayed reflux and cause the phone to have a “uniform temperature rise” inside after long-time high-load operation, thereby completely failing the convection and resulting in poor heat dissipation.

Therefore, it is necessary to provide a new heat dissipation module to solve the above problems.

### SUMMARY

The technical problem to be solved by the present disclosure is to provide a heat dissipation module which has an active heat dissipation function and a fast heat dissipation speed, and saves installation space.

In order to solve the above technical problems, an embodiment of the present disclosure provides a heat dissipation module, including a vapor chamber and a sound-producing device attached and fixed to the vapor chamber.

The vapor chamber includes a vapor chamber body having a receiving cavity therein, a capillary wick received in the receiving cavity, and an opening arranged on a side of the vapor chamber body close to the sound-producing device; the opening connects the receiving cavity with an external environment, the sound-producing device is supported by the vapor chamber body and partially fixed to the opening to seal the opening, and the receiving cavity is filled with heat dissipation liquid; the sound-producing device includes a magnetic circuit unit spaced apart from the vapor chamber, and a first vibration unit and a second vibration unit disposed on opposite sides of the magnetic circuit unit, and the magnetic circuit unit drives the first vibration unit and the second vibration unit to vibrate.

The sound-producing device further includes a first frame, one end of the first frame is fixed to a side of the magnetic circuit unit close to the vapor chamber, and another end of the first frame is supported by the vapor chamber and arranged around the opening.

The first vibration unit includes a first diaphragm fixed to a side of the first frame close to the vapor chamber, and a first voice coil driving the first diaphragm to vibrate and produce sound; and the first diaphragm is arranged directly opposite to the opening to seal the opening.

As an improvement, the capillary wick is arranged in an annular shape in the receiving cavity, and the opening cuts the capillary wick to form two break ends; the heat dissipation module further includes a first one-way valve and a second one-way valve, the first one-way valve and the second one-way valve are sealed and arranged in the receiving cavity, respectively, and the first one-way valve and the second one-way valve are spaced apart from each other and arranged on opposite sides of the first diaphragm, and seal the two break ends of the capillary wick, respectively.

As an improvement, at least a portion of the first diaphragm is inserted into the opening.

As an improvement, the first diaphragm includes a first fixing portion in an annular shape, a first folded ring portion formed by bending and extending, in a direction away from the first frame, from an inner periphery of the first fixing portion and at least partially inserted into the opening, a first vibration portion formed by bending and extending, in the direction away from the first frame, from an inner periphery of the first folded ring portion, and a first dome covered and fixed to the first vibration portion; the first fixing portion is fixed between the vapor chamber body and the first frame along both sides of a vibration direction of the first vibration unit, respectively, and the first voice coil is fixed to a side of the first vibration portion away from the vapor chamber body.

As an improvement, the heat dissipation module further includes a heat insulation film, and the heat insulation film is attached and fixed to a surface of a side of the magnetic circuit unit close to the vapor chamber.

As an improvement, the heat dissipation module further includes a second frame, the second frame is fixed to an outer periphery of the magnetic circuit unit; the second vibration unit includes a second diaphragm with an outer periphery thereof fixed to a side of the second frame away from the vapor chamber, and a second voice coil driving the second diaphragm to vibrate and produce sound, the magnetic circuit unit is provided with a first magnetic gap and a second magnetic gap surrounding the first magnetic gap, the first voice coil is inserted and suspended in the first magnetic gap, and the second voice coil is inserted and suspended in the second magnetic gap.

As an improvement, the magnetic circuit unit includes a yoke in an annular shape arranged on a side of the first frame away from the vapor chamber, and a magnet assembly fixed to the yoke; the yoke includes a yoke bottom wall in an annular shape and a yoke side wall formed by bending and extending, toward a direction close to the vapor chamber, from an inner periphery of the yoke bottom wall; the magnet assembly includes a lower clamping plate fixed to the side of the first frame away from the vapor chamber, a first main magnet and an auxiliary magnet that are stacked and fixed to a side of the lower clamping plate away from the first frame, and a second main magnet stacked and fixed to a side of the yoke bottom wall away from the first frame; the first main magnet is fixed to a side of the yoke bottom wall close to the first frame; the first main magnet and the yoke side wall are spaced apart from each other to form the first magnetic gap; the first main magnet and the auxiliary magnet are spaced apart from each other to form a gap in an annular shape, and the second voice coil is at least partially inserted into the gap.

As an improvement, the heat dissipation module further includes an upper clamping plate, the upper clamping plate is stacked and fixed to a side of the auxiliary magnet away from the lower clamping plate, the yoke bottom wall and the upper clamping plate are spaced apart to form a gap opening, and the gap and the gap opening jointly form the second magnetic gap.

As an improvement, the second main magnet is penetrated along a vibration direction of the second vibration unit to form a through hole, and the through hole is directly opposite to a space surrounded by the yoke side wall.

As an improvement, the second diaphragm is provided with a sound outlet hole penetrating therethrough, and the sound outlet hole and the through hole are correspondingly arranged and connected to each other.

As an improvement, the heat dissipation module further includes an elastic support assembly fixed to the second frame, the elastic support assembly includes an auxiliary diaphragm fixed to a side of the second frame close to the vapor chamber, an elastic portion fixed to a side of the second frame close to the first vibration unit, and a conductive member formed by bending and extending, in a direction away from the second frame, from an inner periphery side of the elastic portion, the conductive member is configured to form electrical connections with the first voice coil and the second voice coil, respectively, and the elastic portion is fixed between the auxiliary diaphragm and the second frame.

Compared with the related art, in the heat dissipation module of the present disclosure, a sound-producing device is attached and fixed to a vapor chamber, the vapor chamber includes a vapor chamber body having a receiving cavity therein, a capillary wick received in the receiving cavity, and an opening arranged on a side of the vapor chamber body close to the sound-producing device; the opening connects the receiving cavity with an external environment, the sound-producing device is supported by the vapor chamber body and partially fixed to the opening to seal the opening, and the receiving cavity is filled with heat dissipation liquid; the magnetic circuit unit drives a first vibration unit and a second vibration unit to vibrate; one end of a first frame is fixed to a side of the magnetic circuit unit close to the vapor chamber, and another end of the first frame is supported by the vapor chamber and arranged around the opening; the first vibration unit includes a first diaphragm fixed to the first frame, and a first voice coil driving the first diaphragm to vibrate and produce sound; the first diaphragm is arranged directly opposite to the opening to seal the opening, and the first voice coil drives the first diaphragm to vibrate, which can actively increase of the flow speed of the heat dissipation liquid and improve the heat dissipation performance of the vapor chamber to the sound-producing device; meanwhile, the first diaphragm is arranged in the opening, which effectively reduces the overall installation space of the heat dissipation module.

### BRIEF DESCRIPTION OF DRAWINGS

The technical solutions according to the embodiments of the present disclosure will be described clearly and completely below in conjunction with the drawings according to the embodiments of the present disclosure. It is appreciated that, the drawings described below are only some embodiments of the present disclosure, and those skilled in the art can obtain other drawings according to these drawings without creative efforts. In the drawings:

FIG. 1 is a structural schematic diagram of a heat dissipation module according to an embodiment of the present disclosure.

FIG. 2 is a partial structural exploded view of a heat dissipation module according to an embodiment of the present disclosure.

FIG. 3 is a partial schematic diagram of a cross-sectional view along line A-A in FIG. 1.

FIG. 4 is an exploded view of a sound-producing device in FIG. 2.

FIG. 5 is a structural schematic diagram of a first diaphragm of a sound-producing device in FIG. 2.

FIG. 6 is a structural schematic diagram of a framework of a sound-producing device in FIG. 2.

FIG. 7 is a cross-sectional view along line B-B in FIG. 2.

### DESCRIPTION OF EMBODIMENTS

The technical solutions according to the embodiments of the present disclosure will be described clearly and completely below in conjunction with the drawings according to the embodiments of the present disclosure. It is appreciated that, the described embodiments are only part of the embodiments of the present disclosure, rather than all the embodiments. According to the embodiments of the present disclosure, all other embodiments obtained by those skilled in the art without creative efforts shall fall within the protection scope of the present disclosure.

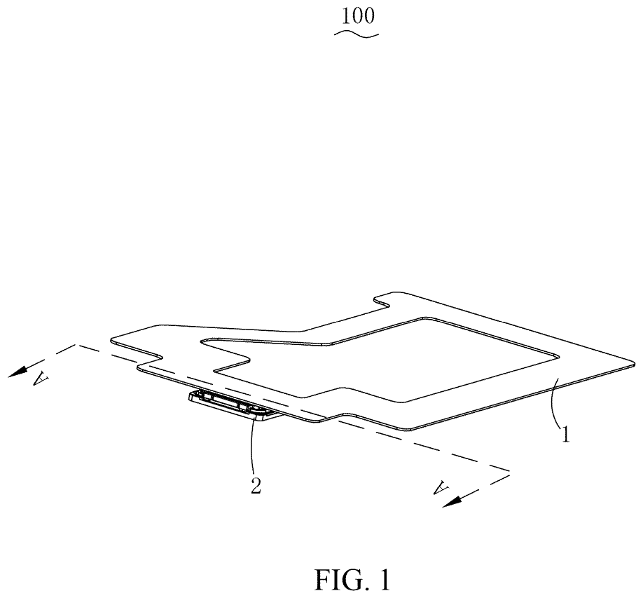

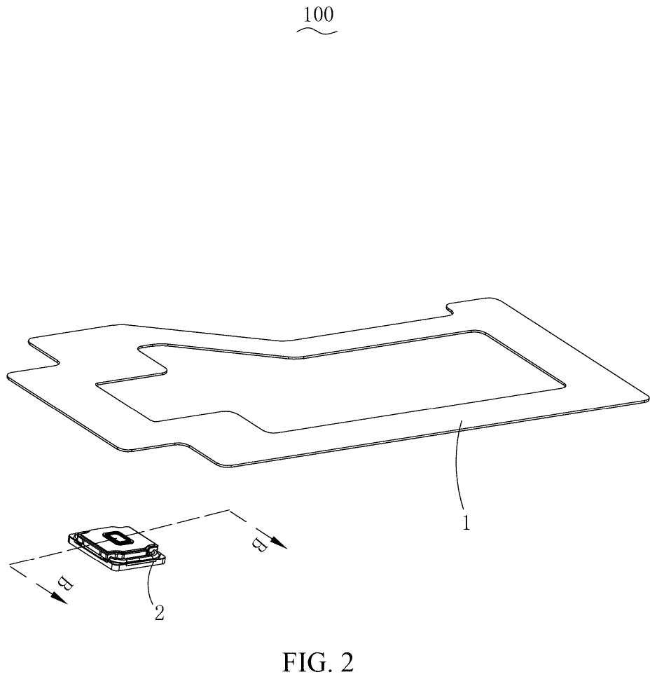

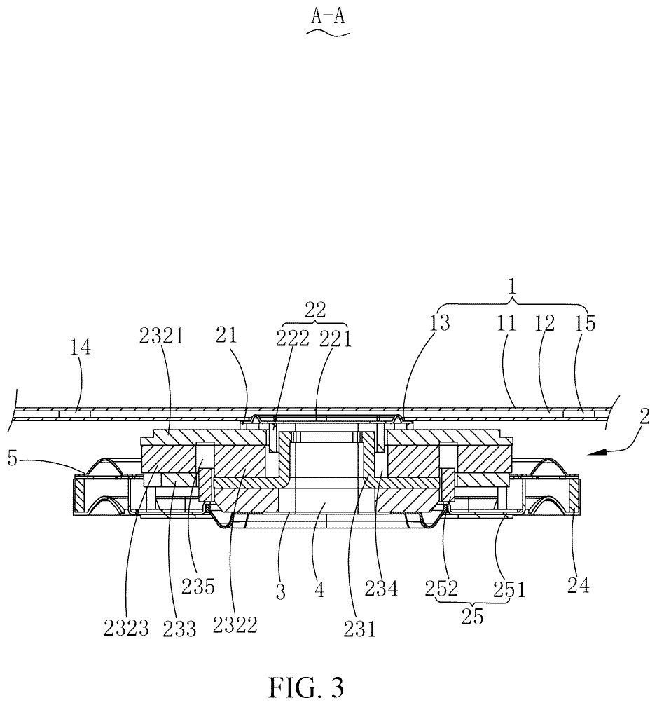

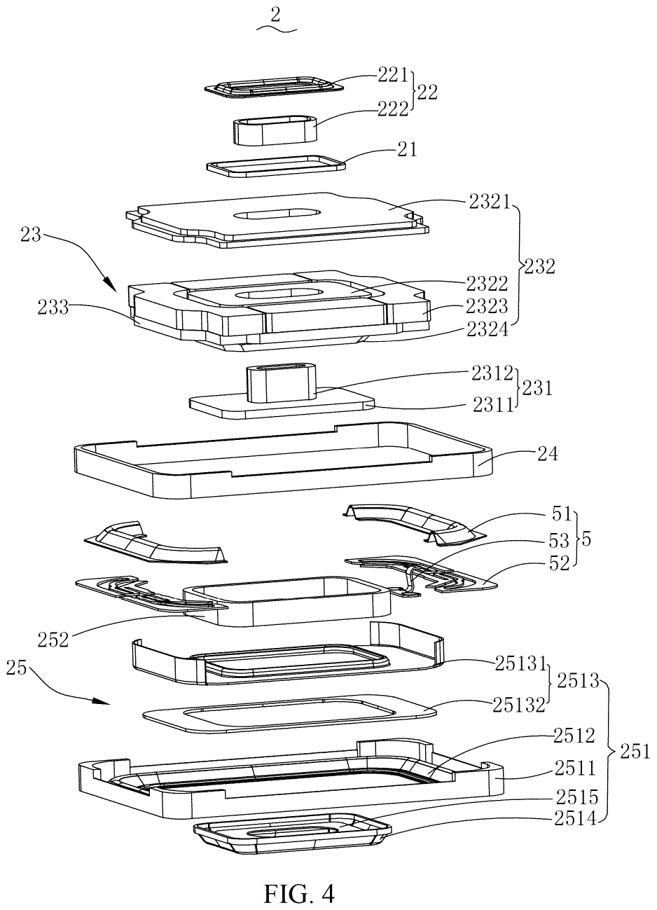

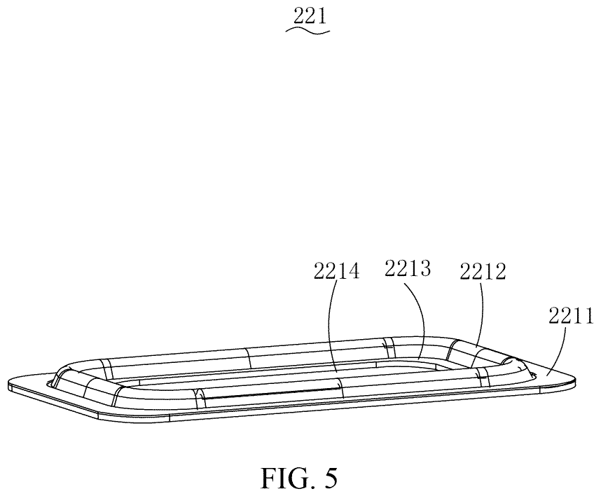

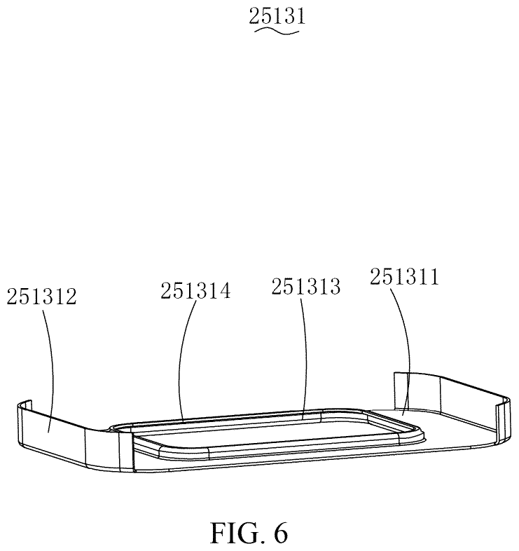

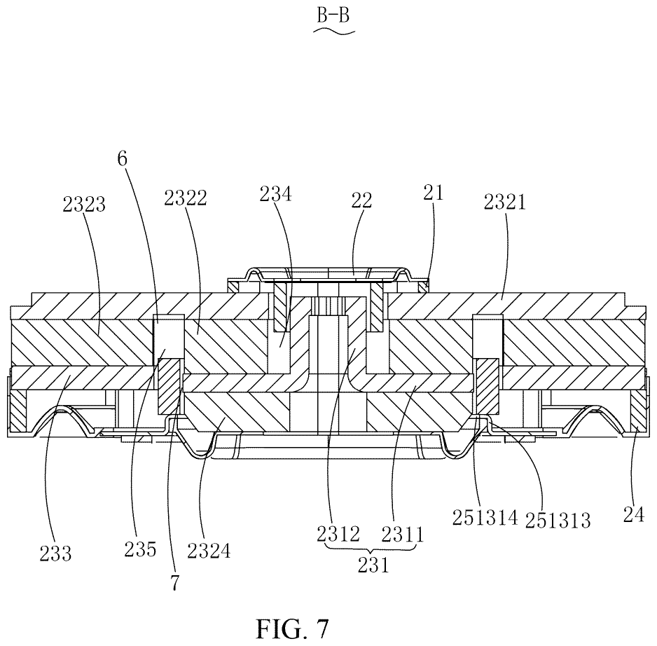

Referring to FIG. 1 to FIG. 7, the embodiments of the present disclosure provide a heat dissipation module 100, including a vapor chamber 1 and a sound-producing device 2 attached and fixed to the vapor chamber 1. The vapor chamber 1 is configured to dissipate heat from the sound-producing device 2 during operation.

The vapor chamber 1 includes a vapor chamber body 11 having a receiving cavity 12, a capillary wick (not shown in the drawings) received in the receiving cavity, and an opening 13 arranged on a side of the vapor chamber body 11 close to the sound-producing device 2. The opening 13 connects the receiving cavity 12 with an external environment, the sound-producing device 2 is supported by the vapor chamber body 11 and partially inserted into and fixed to the opening 13 to seal the opening 13, and the receiving cavity 12 is filled with heat dissipation liquid. By arranging the sound-producing device 2 in the opening 13, the vibration of the sound-producing device 2 actively drives the flow of the heat dissipation fluid to remove the heat of the heat dissipation module 100, and the heat is discharged through the vapor chamber body 11, thereby improving the heat dissipation performance of the heat dissipation module 100.

In some embodiments, the vapor chamber 1 can be extended to an audio end, thereby effectively utilizing the overall layout of the existing mobile phone without adding extra space. A separate vibration unit is used to push the heat dissipation liquid in the vapor chamber 1 to achieve a rapid heat dissipation effect.

In some embodiments, the sound-producing device 2 includes a first frame 21, a first vibration unit 22, a magnetic circuit unit 23, a second frame 24 and a second vibration unit 25. The magnetic circuit unit 23 is spaced apart from the vapor chamber 1 and the magnetic circuit unit 23 drives the first vibration unit 22 and the second vibration unit 25 to vibrate.

The first frame 21 is configured to install and fix the first vibration unit 22. One end of the first frame 21 is fixed to the side of the magnetic circuit unit 23 close to the vapor chamber 1, and another end of the first frame 21 is supported by the vapor chamber 1 and arranged around the opening 13.

The first vibration unit 22 includes a first diaphragm 221 fixed to a side of the first frame 21 close to the vapor chamber 1, and a first voice coil 222 driving the first diaphragm 221 to vibrate and produce sound. The first diaphragm 221 is arranged directly opposite to the opening 13 to seal the opening 13. By combining the vapor chamber 1 with the first diaphragm 221 of the sound-producing device 2, the passive heat dissipation structure of the vapor chamber 1 is transformed into an active heat dissipation structure. By driving the first diaphragm 221 to vibrate through the first voice coil 222, the flow speed of the heat dissipation liquid can be actively increased, thereby improving the heat dissipation performance of the vapor chamber 1 to the sound-producing device 2. Meanwhile, the first diaphragm 221 is arranged in the opening 13, which effectively reduces the overall installation space of the heat dissipation module 100.

The second frame 24 is fixed to an outer periphery of the magnetic circuit unit 23.

The second vibration unit 25 includes a second diaphragm 251 with an outer periphery thereof fixed to the side of the second frame 24 away from the magnetic circuit unit 23, and a second voice coil 252 driving the second diaphragm 251 to vibrate and produce sound. By using the single magnetic circuit unit 23 to drive the first vibration unit 22 and the second vibration unit 25 to vibrate and produce sound, the acoustic performance of the sound-producing device 2 can be improved.

In some embodiments, the capillary wick is arranged in an annular shape in the receiving cavity, and the opening 13 cuts the capillary wick to form two break ends. The heat dissipation module 100 further includes a first one-way valve 14 and a second one-way valve 15, the first one-way valve 14 and the second one-way valve 15 are sealed and arranged in the receiving cavity 12, respectively, and the first one-way valve 14 and the second one-way valve 15 are spaced apart from each other and arranged on opposite sides of the first diaphragm 221, and seal the two break ends of the capillary wick, respectively. By arranging the first one-way valve 14 and the second one-way valve 15 on both sides of the first diaphragm 221, the flow directions of the first one-way valve 14 and the second one-way valve 15 are the same. For example, the heat dissipation liquid can pass through the first one-way valve 14, the first diaphragm 221 and the second one-way valve 15 arranged in circulation in sequence, so that the heat dissipation liquid in the flow process can take out the heat emitted by the first vibration unit 22 during operation, thereby achieving the effect of active vibration heat dissipation. The heat dissipation liquid can also pass through the second one-way valve 15, the first diaphragm 221 and the first one-way valve 14 arranged in circulation in sequence, and its function is the same as described above, which will not be elaborated in the present disclosure.

In some embodiments, at least a portion of the first diaphragm 221 is inserted into the opening 13.

In some embodiments, the first diaphragm 221 includes a first fixing portion 2211 in an annular shape, a first folded ring portion 2212 formed by bending and extending, in a direction away from the first frame 21, from an inner periphery of the first fixing portion 2211 and at least partially inserted into the opening 13, a first vibration portion 2213 formed by bending and extending, in the direction away from the first frame 21, from an inner periphery of the first folded ring portion 2212, and a first dome 2214 covered and fixed to the first vibration portion 2213. The first fixing portion 2211 is fixed between the vapor chamber body 11 and the first frame 21 along both sides of a vibration direction of the first vibration unit 22, respectively, and the first voice coil 222 is fixed to a side of the first vibration portion 2213 away from the vapor chamber body 11. By energizing the first voice coil 222, the first vibration portion 2213 is driven to vibrate, and the first dome 2214 is provided on the first vibration portion 2213 to further enhance the vibration performance of the first diaphragm 221.

In some embodiments, the heat dissipation module 100 further includes a heat insulation film (not shown in the drawings), and the heat insulation film is attached and fixed to a side of a lower clamping plate 2321 close to the vapor chamber 1. By providing the heat insulation film, the heat of the sound-producing device itself can be prevented from affecting the heat dissipation effect of the vapor chamber.

In some embodiments, the magnetic circuit unit 23 is spaced apart from the vapor chamber 1, and the magnetic circuit unit 23 is fixed to a side of the first frame 21 away from the vapor chamber 1.

In some embodiments, the magnetic circuit unit 23 includes a yoke 231 in an annular shape arranged on a side of the first frame 21 away from the vapor chamber 1, and a magnet assembly 232 fixed to the yoke 231. The yoke 231 includes a yoke bottom wall 2311 and a yoke side wall 2312 formed by bending and extending, toward a direction close to the first vibration unit 22, from an inner periphery of the yoke bottom wall 2311. The magnet assembly 232 includes the lower clamping plate 2321 fixed to the side of the first frame 21 away from the vapor chamber 1, a first main magnet 2322 and an auxiliary magnet 2323 that are stacked and fixed to a side of the lower clamping plate 2321 away from the first frame 21, and a second main magnet 2324 stacked and fixed to a side of the yoke bottom wall 2311 away from the first frame 21. The auxiliary magnet 2323 is arranged around the first main magnet 2322 at intervals, and the first main magnet 2322 is fixed to a side of the yoke bottom wall 2311 close to the first frame 21. An inner periphery side of the first main magnet 2322 and the yoke side wall 2312 are spaced apart from each other to form a first magnetic gap 234, and the first voice coil 222 is inserted and suspended in the first magnetic gap 234. The first main magnet 2322 and the auxiliary magnet 2323 are spaced apart from each other to form a gap 6 in an annular shape, and the second voice coil 252 is at least partially inserted into the gap 6.

In some embodiments, the heat dissipation module 100 further includes an upper clamping plate 233, and the upper clamping plate 233 is stacked and fixed to a side of the auxiliary magnet 2323 away from the lower clamping plate 2321. The first main magnet 2322 and the auxiliary magnet 2323 are spaced apart from each other to form the gap 6 in an annular shape. The yoke bottom wall 2311 is further provided with a gap opening 7 in an annular shape which is connected to the gap 6 in the form of a direct opposite, and the gap 6 and the gap opening 7 jointly form a second magnetic gap 235. The upper clamping plate 233 is used to improve the magnetism of the auxiliary magnet 2323.

By fixing the first frame 21 on the side of the lower clamping plate 2321 close to the vapor chamber 1, and installing and fixing the first main magnet 2322 and the auxiliary magnet 2323 on the side of the lower clamping plate 2321 away from the vapor chamber 1, it is convenient to suspend the second voice coil 252 in the second magnetic gap 235, and the second diaphragm 251 is driven to vibrate and produce sound when the magnetic circuit unit 23 and the second voice coil 252 drive each other. By spacing the first main magnet 2322 and the yoke side wall 2312 to form the first magnetic gap 234, the first voice coil 222 can be suspended in the first magnetic gap 234. By driving the first voice coil 222 by the magnetic circuit unit 23, the first voice coil 222 drives the first diaphragm 221 to vibrate and produce sound, thereby achieving a dual diaphragm sounding effect and further improving the acoustic performance of the sound-producing device 2. In addition, by arranging the second main magnetic 2324 on a side of the yoke bottom wall 2311, the magnetic field performance of the first main magnet 2322 can be improved and the magnetism of the magnetic circuit unit 23 can be further improved.

In some embodiments, the vapor chamber 1 is used in conjunction with a simple sound-producing device. As an improvement, the vapor chamber 1 can also be used in conjunction with a sound-producing device or a sound-producing module with a housing.

In some embodiments, the second main magnet 2324 is penetrated along a vibration direction of the second vibration unit 25 to form a through hole 4, and the through hole 4 is directly opposite to a space surrounded by the yoke side wall 2312, which facilitates air release during overall vibration and improves acoustic performance.

In some embodiments, the second diaphragm 251 includes a second fixing portion 2511 in an annular shape fixed to the second frame 24, a second folded ring portion 2512 formed by bending and extending, in a direction away from the second frame 24, from an inner periphery of the second fixing portion 2511, a second vibration portion 2513 formed by bending and extending, in the direction away from the second frame 24, from an inner periphery of the second folded ring portion 2512, a third folded ring portion 2514 formed by bending and extending, in the direction away from the second frame 24, from an inner periphery of the second vibration portion 2513, and a third vibration portion 2515 formed by bending and extending, in the direction away from the second frame 24, from an inner periphery of the third folded ring portion 2514. The second voice coil 252 is fixed to a side of the second vibration portion 2513 close to the first vibration unit 22.

The second diaphragm 251 is provided with a sound outlet hole 3 penetrating therethrough, and the sound outlet hole 3 and the through hole 4 are correspondingly arranged and connected to each other, which facilitates the second vibration unit 25 to vibrate and produce sound and transmit the sound to the external environment.

In some embodiments, the second vibration portion 2513 includes a framework 25131 and a second dome 25132 covered and fixed to a side of the framework 25131 away from the first vibration unit 22. The framework 25131 includes a framework body 251311, a first connection portion 251312 formed by bending and extending, in a direction close to the vapor chamber 1, from the opposite sides of an outer periphery of the framework body 251311, a second connection portion 251313 formed by bending and extending, in the direction close to the vapor chamber 1, from an inner periphery of the framework body 251311, and a installing portion 251314 formed by bending and extending, in a direction close to the second main magnet 2324, from an inner periphery of the second connection portion 251313. The second dome 25132 is covered and fixed to a side of the framework body 251311 away from the vapor chamber 1, and the inner periphery of the second folded ring portion 2512 is fixed to a side of the outer periphery of the framework body 251311 away from the first vibration unit 22. The third folded ring portion 2514 is fixed to a side of the installing portion 251314 away from the first vibration unit 22, and the third folded ring portion 2514 is attached to a side of the second connection portion 251313 close to the second main magnet 2324. The second voice coil 252 is fixed to a side of the installing portion 251314 close to the vapor chamber 1. The framework 25131 facilitates the installation and fixation of the second folded ring portion 2512 and the third folded ring portion 2514, and facilitates the suspension and fixation of the second voice coil 252, so that the installation of the second voice coil 252 is convenient. By providing the second dome 25132 on the framework 25131, the vibration performance of the second vibration portion 2513 is further improved.

In some embodiments, the heat dissipation module 100 further includes an elastic support assembly 5 fixed to the second frame 24. The elastic support assembly 5 includes an auxiliary diaphragm 51 fixed to a side of the second frame 24 close to the vapor chamber 1, an elastic portion 52 fixed to a side of the second frame 24 close to the first vibration unit 22, and a conductive member 53 formed by bending and extending, in a direction away from the second frame 24, from an inner periphery side of the elastic portion 52. The conductive member 53 is configured to form electrical connections with the first voice coil 222 and the second voice coil 252, respectively, and the elastic portion 52 is fixed between the auxiliary diaphragm 51 and the second frame 24. By arranging the auxiliary diaphragm 51 correspondingly to the second diaphragm 251, the vibration performance of the sound-producing device 2 is further improved. In an embodiment, the conductive member 53 and the elastic portion 52 can be a PFC circuit board, which has good elasticity, easy wire installation, and saves space.

Compared with the related art, in the heat dissipation module of the present disclosure, a sound-producing device is attached and fixed to a vapor chamber, the vapor chamber includes a vapor chamber body having a receiving cavity therein, a capillary wick received in the receiving cavity, and an opening arranged on a side of the vapor chamber body close to the sound-producing device; the opening connects the receiving cavity with an external environment, the sound-producing device is supported by the vapor chamber body and partially fixed to the opening to seal the opening, and the receiving cavity is filled with heat dissipation liquid; the magnetic circuit unit drives a first vibration unit and a second vibration unit to vibrate; one end of a first frame is fixed to a side of the magnetic circuit unit close to the vapor chamber, and another end of the first frame is supported by the vapor chamber and arranged around the opening; the first vibration unit includes a first diaphragm fixed to the first frame, and a first voice coil driving the first diaphragm to vibrate and produce sound; the first diaphragm is arranged directly opposite to the opening to seal the opening, and the first voice coil drives the first diaphragm to vibrate, which can actively increase of the flow speed of the heat dissipation liquid and further improve the heat dissipation performance of the vapor chamber to the sound-producing device; meanwhile, the first diaphragm is arranged in the opening, which effectively reduces the overall installation space of the heat dissipation module

The above is only embodiments of the present disclosure. It should be pointed out that, for those skilled in the art, improvements can be made without departing from the creative concept of the present disclosure, but these all fall within the protection scope of the present disclosure.

What is claimed is:

1. A heat dissipation module, comprising a vapor chamber and a sound-producing device fixedly attached to the vapor chamber;
wherein the vapor chamber comprises a vapor chamber body having a receiving cavity therein, a capillary wick received in the receiving cavity, and an opening provided on a side of the vapor chamber body close to the sound-producing device; the opening connects the receiving cavity to an external environment, the sound-producing device is supported by the vapor chamber body and partially fixed to the opening to seal the opening, and the receiving cavity is filled with a heat dissipation liquid;
wherein the sound-producing device comprises a magnetic circuit unit spaced apart from the vapor chamber, and a first vibration unit and a second vibration unit that are disposed on opposite sides of the magnetic circuit unit, and the magnetic circuit unit drives the first vibration unit and the second vibration unit to vibrate;
wherein the sound-producing device further comprises a first frame, one end of the first frame is fixed to a side of the magnetic circuit unit close to the vapor chamber, and another end of the first frame is supported by the vapor chamber and arranged around the opening; and
wherein the first vibration unit comprises a first diaphragm fixed to a side of the first frame close to the vapor chamber, and a first voice coil driving the first diaphragm to vibrate and produce sound; and the first diaphragm is arranged directly opposite to the opening to seal the opening.

2. The heat dissipation module as described in claim 1, wherein
the capillary wick is annularly arranged in the receiving cavity, and the opening cuts the capillary wick to form two break ends; the heat dissipation module further comprises a first one-way valve and a second one-way valve, the first one-way valve and the second one-way valve are sealed and arranged in the receiving cavity, respectively, and the first one-way valve and the second one-way valve are spaced apart from each other and arranged on opposite sides of the first diaphragm, and seal the two break ends of the capillary wick, respectively.

3. The heat dissipation module as described in claim 1, wherein
at least a portion of the first diaphragm is inserted into the opening.

4. The heat dissipation module as described in claim 3, wherein
the first diaphragm comprises a first fixing portion in an annular shape, a first folded ring portion formed by bending and extending, in a direction away from the first frame, from an inner periphery of the first fixing portion and at least partially inserted into the opening, a first vibration portion formed by bending and extending, in the direction away from the first frame, from an inner periphery of the first folded ring portion, and a first dome that covers and is fixed to the first vibration portion; the first fixing portion is fixed between the vapor chamber body and the first frame along both sides of a vibration direction of the first vibration unit, respectively, and the first voice coil is fixed to a side of the first vibration portion away from the vapor chamber body.

5. The heat dissipation module as described in claim 1, further comprising a heat insulation film, wherein the heat insulation film is attached and fixed to a surface of a side of the magnetic circuit unit close to the vapor chamber.

6. The heat dissipation module as described in claim 1, further comprising a second frame, wherein the second frame is fixed to an outer periphery of the magnetic circuit unit; the second vibration unit comprises a second diaphragm with an outer periphery thereof fixed to a side of the second frame away from the vapor chamber, and a second voice coil driving the second diaphragm to vibrate and produce sound, the magnetic circuit unit is provided with a first magnetic gap and a second magnetic gap surrounding the first magnetic gap, the first voice coil is inserted and suspended in the first magnetic gap, and the second voice coil is inserted and suspended in the second magnetic gap.

7. The heat dissipation module as described in claim 6, wherein
the magnetic circuit unit comprises a yoke in an annular shape arranged on a side of the first frame away from the vapor chamber, and a magnet assembly fixed to the yoke; the yoke comprises a yoke bottom wall in an annular shape and a yoke side wall formed by bending and extending an inner periphery of the yoke bottom wall toward a direction close to the vapor chamber; the magnet assembly comprises a lower clamping plate fixed to the side of the first frame away from the vapor chamber, a first main magnet and an auxiliary magnet that are stacked and fixed to a side of the lower clamping plate away from the first frame, and a second main magnet stacked and fixed to a side of the yoke bottom wall away from the first frame;
wherein the first main magnet is fixed to a side of the yoke bottom wall close to the first frame; the first main magnet and the yoke side wall are spaced apart from each other to form the first magnetic gap; the first main magnet and the auxiliary magnet are spaced apart from each other to form a gap in an annular shape, and the second voice coil is at least partially inserted into the gap.

8. The heat dissipation module as described in claim 7, further comprising an upper clamping plate, wherein the upper clamping plate is stacked and fixed to a side of the auxiliary magnet away from the lower clamping plate, the yoke bottom wall and the upper clamping plate are spaced apart to form a gap opening, and the gap and the gap opening jointly form the second magnetic gap.

9. The heat dissipation module as described in claim 7, wherein
the second main magnet is penetrated along a vibration direction of the second vibration unit to form a through hole, and the through hole is directly opposite to a space defined by the yoke side wall.

10. The heat dissipation module as described in claim 9, wherein
the second diaphragm is provided with a sound outlet hole penetrating through the second diaphragm, and the sound outlet hole and the through hole are correspondingly arranged and connected to each other.

11. The heat dissipation module as described in claim 6, further comprising an elastic support assembly fixed to the second frame,
wherein the elastic support assembly comprises an auxiliary diaphragm fixed to a side of the second frame close to the vapor chamber, an elastic portion fixed to a side of the second frame close to the first vibration unit, and a conductive member formed by bending and extending an inner periphery side of the elastic portion in a direction away from the second frame, the conductive member is configured to form electrical connections with the first voice coil and the second voice coil, respectively, and the elastic portion is fixed between the auxiliary diaphragm and the second frame.
